(19) United States
(12) Patent Application Publication
(10) Pub. No.: US 2008/0277665 A1
(43) Pub. Date: Nov. 13, 2008

(54) SEMICONDUCTOR DEVICE, NONVOLATILE MEMORY DEVICE AND METHOD FOR FABRICATING THE SAME

(75) Inventors: Cha-Deok DONG, Ichon-shi (KR); Il-Seok Seo, Ichon-shi (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Ichon-shi (KR)

(21) Appl. No.: 11/967,199

(22) Filed: Dec. 30, 2007

(30) Foreign Application Priority Data
May 9, 2007 (KR) 10-2007-0045018

(51) Int. Cl. H01L 21/36; H01L 29/04; H01L 29/788

(52) U.S. Cl. 257/66; 257/74; 438/486; 257/E29.003; 257/E29.3; 257/E21.461

(57) ABSTRACT

A semiconductor device includes a conductive layer including a first and a second polysilicon layers having different grain boundaries, wherein a portion or an entire region of the first polysilicon layer is crystallized and wherein a grain boundary in a crystallized region is bigger than the grain boundary of the second polysilicon layer.

### CROSS-REFERENCE TO RELATED APPLICATIONS

The present invention claims priority of Korean patent application number 10-2007-0045018, filed on May 9, 2007, which is incorporated by reference in its entirety.

### BACKGROUND OF THE INVENTION

The present invention relates to a semiconductor fabrication technology and, more particularly, to a semiconductor device with improved doping concentration distribution.

A NAND flash memory device, which is nonvolatile, includes a plurality of cells which are connected in series to form a string for increased integration. The NAND flash memory device can substitute for a memory stick, a universal serial bus (USB) driver and a hard disk, and it has become more widely used.

Recently, the memory of the NAND flash memory device has evolved from a single level cell (SLC) memory to include multi level cell (MLC) memory for higher integration and larger capacity. An important requirement of the MLC memory is a stable distribution of threshold voltages because of the increased number of states for one cell. Repetitive cycling including programming and erasing can cause a degradation in the characteristics of the flash memory. This can be improved through the improvement of the threshold voltage distribution.

The improvement of the threshold voltage distribution is critical in implementing the MLC memory. However, there are difficulties in improving the distribution of threshold voltages due to several factors in the conventional fabrication processes of the memory device. For example, one of these factors is shown in a process of forming a floating gate.

In a device in which line width is more than 70 nm, a floating gate is formed through a self-aligned shallow trench isolation (SA-STI) process in order to solve a problem such as a moat in the conventional self aligned floating gate (SAFG) process. Referring to the formation process of the floating gate, an undoped polysilicon layer and an impurity-doped polysilicon layer are sequentially deposited, dopants in the doped polysilicon layer, are diffused into the undoped polysilicon layer through a heat treatment, and a uniform doping concentration is formed in the floating gate.

However, in the case of depositing the doped polysilicon layer over the undoped polysilicon layer regardless of physical stress caused by a doping profile in the conventional method of fabricating the nonvolatile memory device, an interface characteristic between the layers is degraded so that the uniform diffusion of the dopants by the subsequent heat treatment is difficult. Thus, it becomes difficult to form a floating gate with a uniform doping concentration. In the case that the doping concentration of the floating gate is not uniform, the distribution of threshold voltages is degraded and thus the operating characteristics of the device are degraded.

### SUMMARY OF THE INVENTION

The present invention relates to a semiconductor device which includes a conductive layer (i.e., a gate) which is made of two layers having a uniform doping concentration and a method of fabricating the same.

Also, the present invention relates to a nonvolatile memory device which includes a floating gate of a multilayered structure having a uniform doping density and a method of fabricating the nonvolatile memory device.

In accordance with a first aspect of the present invention, there is provided a semiconductor device. The semiconductor device includes a conductive layer including a first and a second polysilicon layers having different grain boundaries, wherein a portion or an entire region of the first polysilicon layer is crystallized and wherein a grain boundary in a crystallized region is bigger than the grain boundary of the second polysilicon layer.

In accordance with a second aspect of the present invention, there is provided a method of forming a conductive layer in a semiconductor device, the method includes forming a first polysilicon layer over a substrate, crystallizing the first polysilicon layer, thereby forming locally or entirely crystallized first polysilicon layer, and forming a second polysilicon layer over the first polysilicon layer.

In accordance with a third aspect of the present invention, there is provided a nonvolatile memory device. The nonvolatile memory device includes a floating gate including a first and a second polysilicon layers having different grain boundaries, wherein a portion or an entire region of the first polysilicon layer is crystallized and wherein a grain boundary in a crystallized region is greater than a grain boundary of the second polysilicon layer.

In accordance with a fourth aspect of the present invention, there is provided a method of forming a floating gate in a nonvolatile memory device. The method includes forming a first polysilicon layer over a substrate, crystallizing the first polysilicon layer, thereby forming locally or entirely crystallized first polysilicon layer, and forming a second polysilicon layer over the first polysilicon layer.

### BRIEF DESCRIPTION OF THE DRAWINGS

FIG. 1 illustrates a cross-sectional view of a nonvolatile memory device according to an embodiment of the present invention.

FIGS. 2A to 2E illustrate cross-sectional views of a method of fabricating a nonvolatile memory device according to an embodiment of the present invention.

FIG. 3 is a micrograph of a section of a floating gate according to the prior art and an embodiment of the present invention.

FIG. 4 illustrates a graph of cell threshold voltages after a programming operation is performed in an incremental step pulse programming scheme (ISPP) method according to the prior art and an embodiment of the present invention.

FIG. 5 illustrates a graph of a ratio for a cell threshold voltage to a number of erase/write (E/W) cycling according to the prior art and an embodiment of the present invention.

### DETAILED DESCRIPTION OF THE SPECIFIC EMBODIMENTS

Hereinafter, the present invention will be described in detail with reference to the drawings. Also, the thicknesses of layers and regions illustrated in the drawings are exaggerated to ensure the clarification of the present invention and, in the description, a layer which is formed on another layer or a substrate actually means that the layer can be directly formed on another layer or the substrate or a third layer can be interposed between the layer and another layer or the substrate. Further, elements designated by the same reference numeral in different drawings or different parts of the specification refer to the same element and a capital letter included in a reference numeral designate that a portion of the same element is modified by a formation process, for example, an etching process (or a polishing process).

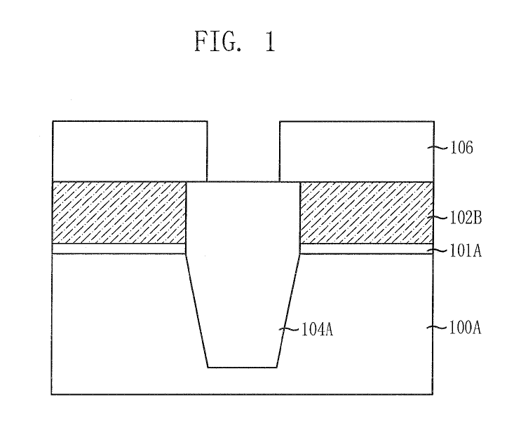

FIG. 1 illustrates a cross-sectional view of a nonvolatile memory device according to an embodiment of the present invention.

Referring to FIG. 1, the nonvolatile memory device according to the embodiment of the present invention includes a plurality of memory cells. Each of the memory cells includes a floating gate and the floating gate has a first polysilicon layer 102B of which a portion or the entire region is crystallized so that a grain size of the portion or the entire region is enlarged and a second polysilicon layer 106 which is formed on the first polysilicon layer 102B has a grain size smaller than that of the first polysilicon layer 102B.

The first polysilicon layer 102B is formed as an undoped polysilicon layer. After the second polysilicon layer 106 is formed as a doped polysilicon layer, the dopants doped on the second polysilicon layer 106 are diffused into the first polysilicon layer 102B through a heat treatment and thus a uniform doping concentration is formed in the floating gate because of the difference in grain size in the two layers. Reference numerals 100A, 101A, 104A represent a substrate, a tunneling isolation layer and an isolation layer, respectively.

Accordingly, the dopants diffused into the first polysilicon layer 102B are extremely important to form the floating gate having the uniform doping concentration. Since the first polysilicon layer 102B is formed out of a polycrystalline layer, the concentration of the dopants diffused into the first polysilicon layer 102B is very weak in the conventional method. Thus, in accordance with the embodiment of the present invention, the first polysilicon layer 102B is crystallized for the enlargement of the grain size so that the diffusion of the dopants is improved in the first polysilicon layer 102B.

The method of fabricating the nonvolatile memory device is illustrated in FIG. 1 in accordance with the embodiment of the present invention.

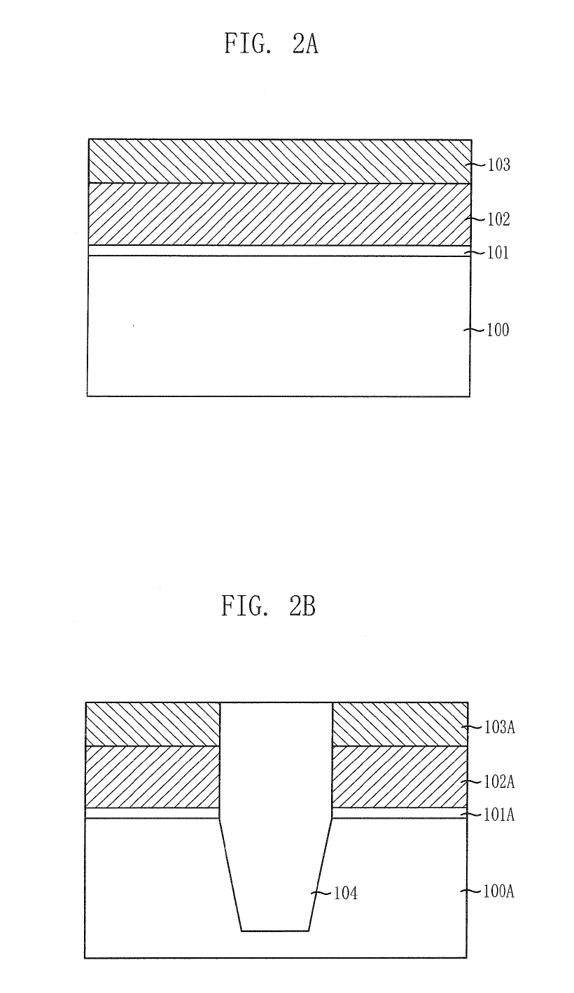

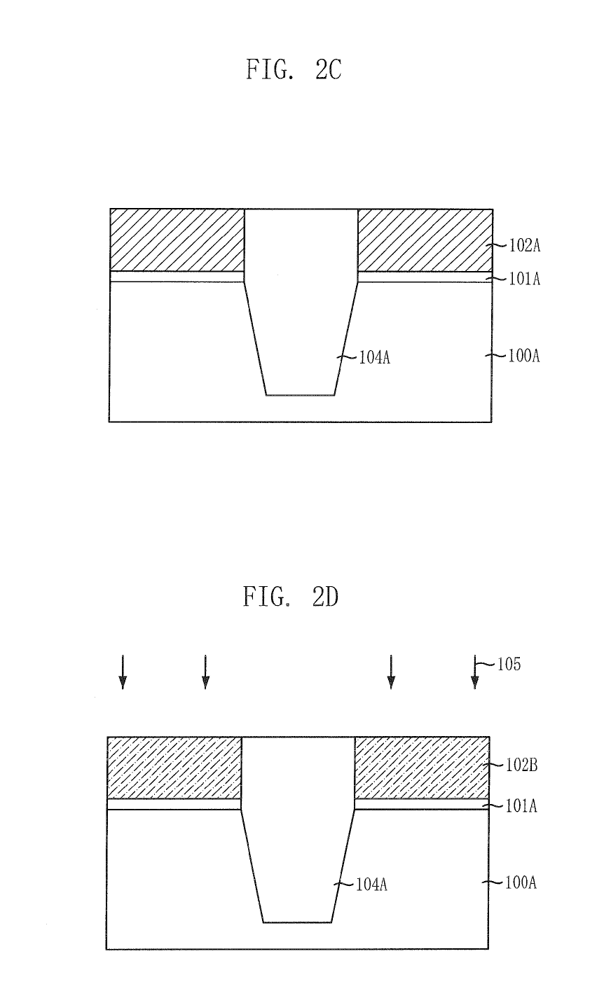

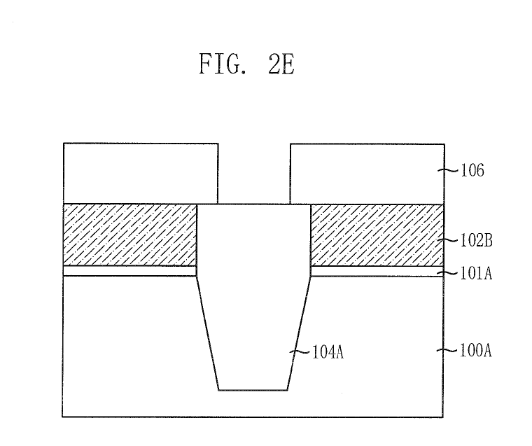

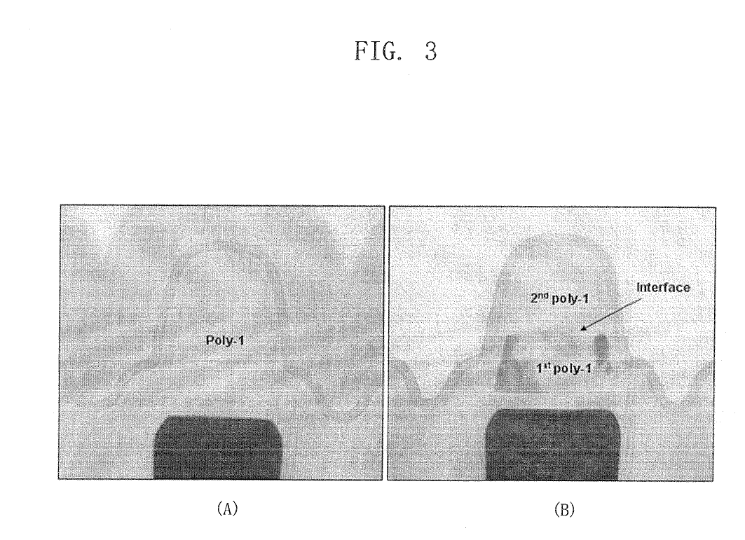

FIGS. 2A to 2E illustrate cross-sectional views of the method of fabricating the nonvolatile memory device according to the embodiment of the present invention. Here, the method of forming the floating gate of a NAND flash memory device using a SA-STI process will be described.

As shown in FIG. 2A, a tunneling insulation layer 101, in which a Fouler-Nordheim (F-N) tunneling occurs, is formed over a substrate 100. At this time, the tunneling insulation layer 101 includes an oxide layer, i.e., a silicon oxide (SiO₂) layer, or in a multilayered structure of a silicon oxide (SiO₂) layer and a nitride layer, i.e., a silicon nitride (Si₃N₄) layer. In order to form the tunneling insulation layer 101, a dry oxidation, a wet oxidation or a radical oxidation is used.

The first polysilicon layer 102 is formed on the tunneling insulation layer 101 as a lower layer of the floating gate. At this time, the first polysilicon layer 102 is formed by a low pressure chemical vapor deposition (LPCVD) method using silane (SiH₄) as a source gas. Also, the first polysilicon layer 102 is formed to have a thickness ranging from approximately 30 percent to approximately 50 percent of the entire thickness of the floating gate.

Meanwhile, the first polysilicon layer 102 can also be formed out of a doped polysilicon layer which is doped at a lower concentration than the second polysilicon layer 106 (see FIG. 2e), i.e., at a concentration of under approximately 1.0×10²⁰ ions/cm², and preferably, in a range from approximately 1.0×10¹⁰ ions/cm² to approximately 1.0×10²⁰ ions/cm². In this case, phosphine (PH₃) can be used as the dopant.

The heat treatment is performed to crystallize a portion or the entire region of the first polysilicon layer 102. At this time, the heat treatment is carried out by a rapid thermal process (RTP), a furnace annealing process or a laser annealing process. For example, the RTP is performed in a range from approximately 600° C. to approximately 1,000° C. for several to tens of seconds, preferably, five to one hundred seconds. The furnace annealing process is performed in a range from approximately 600° C. to approximately 900° C. for several minutes to tens of minutes, preferably, five to one hundred minutes. An island-type crystal is formed at an interface of the tunneling insulation layer 101 or a crystallization progresses on the whole.

Meanwhile, instead of the heat treatment, a chemical vapor deposition (CVD) process or a thermal oxidation process can be used as the method of crystallizing a portion or the entire region of the first polysilicon layer 102. A thin film is formed over the first polysilicon layer 102 using the CVD process or the thermal oxidation process, and the crystallization of a portion or the entire region of the first polysilicon layer 102 is performed through a heating resource used in the CVD process or the thermal oxidation process. For example, the CVD process is performed at a temperature of more than approximately 600° C., and preferably, at a temperature ranging from approximately 600° C. to approximately 1,000° C. The thin film is formed through the CVD process or the thermal oxidation process. The thin film is a type of oxide layer and can be tetraethyleorthosilicate (TEOS) or hot temperature oxide (HTO). The thermal oxidation process can be performed using dry or wet radical ions.

The thin film, formed on the first polysilicon layer 102 through the CVD process or the thermal oxidation process, is formed at a thickness which can be entirely removed by a subsequent cleaning process. For example, the thickness of the thin film can range from approximately 30□ to approximately 100□. Also, the thermal oxidation process changes a portion of the first polysilicon layer 102 into a silicon oxide (SiO₂) layer through the reaction of oxygen (O₂) with silicon of the first polysilicon layer 102. Thus, the thickness loss of the first polysilicon layer 102 is inevitable. Therefore, the silicon oxide (SiO₂) layer can be made as thin as possible to minimize a thickness loss of the first polysilicon layer 102.

Meanwhile, the cleaning process to remove the thin film formed through the CVD process or the thermal oxidation process is performed in a wet etching process using a standard cleaning-1 (SC-1), a solution in which NH₄OH, H₂O₂ and H₂O are mixed in a given ratio, and dilute hydrofluoride (DHF). After the cleaning process, a chemical oxide (or a native oxide) is controlled to be less than approximately 10□.

Then, a hard mask 103 is formed on the first polysilicon layer 102. At this time, the hard mask 103 not only protects the first polysilicon layer 102 when an etching process is performed to form a subsequent trench but functions as a polish stop layer when a subsequent isolation layer planarization process is performed, for example, a chemical mechanical polishing (CMP) process. The hard mask 103 is formed out of a material having a high selective etching ratio for the first polysilicon layer 102, for example, a nitride layer, and preferably, a silicon nitride (Si₃N₄) layer.

Meanwhile, a buffer layer (not illustrated) can be formed over the first polysilicon layer 102 before the hard mask 103 is formed. At this time, the buffer layer protects the first polysilicon layer 102 from stress caused by the formation process of the hard mask 103. For example, such a buffer layer is formed out of a silicon oxide (SiO₂) layer through an oxidation process.

As shown in FIG. 2B, the hard mask 103A, the first polysilicon layer 102A, the tunneling insulation layer 101A and the substrate 100A are selectively etched by using a shallow trench isolation (STI) etching process. Thus, a trench having a given depth (not illustrated) is formed in the substrate 100A. Then, an isolation layer 104 is formed to fill in the trench. At this time, the isolation layer 104 can be formed to have a single layer or a multilayered structure, considering a high aspect ratio. For example, in the case that the isolation layer 104 is formed in a single layer, a high concentration plasma (HDP) layer having an excellent gap-filling characteristic can be used. In the case that the isolation layer 104 is formed in a multilayered structure, an HDP layer, a spin on glass (SOG) layer and another HDP layer can be sequentially formed. Here, a PSZ (polysilazane) layer can be used as the SOG layer.

As shown in FIG. 2C, the hard mask 103A (see FIG. 2B) is removed. For example, in the case that the hard mask 103A is formed out of a silicon nitride (Si₃N₄) layer, the process of removing the hard mask 103A is performed by using a phosphoric acid (H₃PO₄) solution. During such a process, a portion of the isolation layer 104A can also be etched.

As shown in FIG. 2D, a thermal treatment 105 is performed to crystallize a portion or the entire region of the first polysilicon layer 102B. Here, in the case that the thermal treatment on the first polysilicon layer 102B is already performed in FIG. 2A, there is no need to perform the thermal treatment 105. The thermal treatment 105 is the same as the thermal treatment performed in FIG. 2A. After performing the thermal treatment, a cleaning process can be performed.

As shown in FIG. 2E, the second polysilicon layer 106 is formed on the first polysilicon layer 102B. At this time, the second polysilicon layer 106 is formed out of an impurity-doped polysilicon layer. Also, the second polysilicon layer 106 is formed to have a higher concentration than the first polysilicon layer 102B, for example, a concentration ranging from approximately 1.0×10²⁰ ions/cm² to approximately 1.0×10²¹ ions/cm². Also, the second polysilicon layer 106 is formed to have a thickness ranging from approximately 50 percent to approximately 70 percent of the entire thickness of the floating gate. For example, the second polysilicon layer 106 is formed by the LPCVD method using SiH₄ as a source gas and phosphine (PH₃) as a doping gas.

Then, the dopants doped in the second polysilicon layer 106 are diffused into the first polysilicon layer 102B by a heat treatment and thus the floating gate having a uniform doping concentration can be obtained.

Since subsequent processes are the same as the conventional processes, they will not be described.

Meanwhile, in the method of fabricating the nonvolatile memory device according to the embodiment of the present invention, the floating gate of a NAND flash memory device is described based on the SA-STI process. However, the present invention can also be applied to an advanced self-aligned shallow trench isolation (ASA-STI) process. In this case, the floating gate is not formed in a single layer but in a multilayered structure.

In detail, a first polysilicon layer, which is a lower layer of the floating gate, is formed as an undoped polysilicon layer. After the formation of the first polysilicon layer, a second polysilicon layer, which is an upper layer of the floating gate, is formed as a doped polysilicon layer using an ex-situ process. At this time, a thermal treatment, for example, the RTP or a furnace annealing process, is performed on the first polysilicon layer before the formation of the second polysilicon layer so that a portion or the entire region of the first polysilicon layer is crystallized. Thus, a grain size of the first polysilicon layer is enlarged. Also, a cleaning process to remove a thin film, for example, TEOS, HTO or a chemical oxide layer (or a native oxide layer), formed at the upper side of the first polysilicon layer can be performed by a wet etching method using DHF or buffered oxide etchant (BOE) after the thermal treatment.

FIG. 3 (A) illustrates a micrograph of a section of the single-layered floating gate formed by the prior art, and FIG. 3 (B) illustrates a micrograph of a section of the multi-layered floating gate formed by an embodiment of the present invention.

As shown in FIG. 3, there is almost no difference between the floating gate fabricated by the prior art and the floating gate fabricated by the present embodiment of the present invention in their structures. Even though an interface (an interface of a portion in which the native oxide or the CVD layer is removed) is formed between the first polysilicon layer and the second polysilicon layer, the reliability of the present invention is excellent.

The method of forming such a multilayered floating gate is mainly used in a NAND flash memory device or a NOR type flash memory device, line width of which is more than 70 nm. In a 60 nm memory device, since it is difficult to pattern a second polysilicon layer through an etching process due to limits of the exposure apparatus, both an undoped polysilicon layer and a doped polysilicon layer are formed by an in-situ process in the same chamber when a single floating gate is formed. However, after a high thermal budget, since such undoped and doped layers are almost the same as a single layer, the formation of the layers as such may not have any significance.

Accordingly, in the embodiment of the present invention, the first and the second polysilicon layers are formed by an ex-situ process and the first and the second polysilicon layers are crystallized through the thermal treatment or the thermal treatment is performed on the first polysilicon layer before the second polysilicon layer is deposited so that the first polysilicon layer is crystallized and thus the characteristic of the first polysilicon layer is secured.

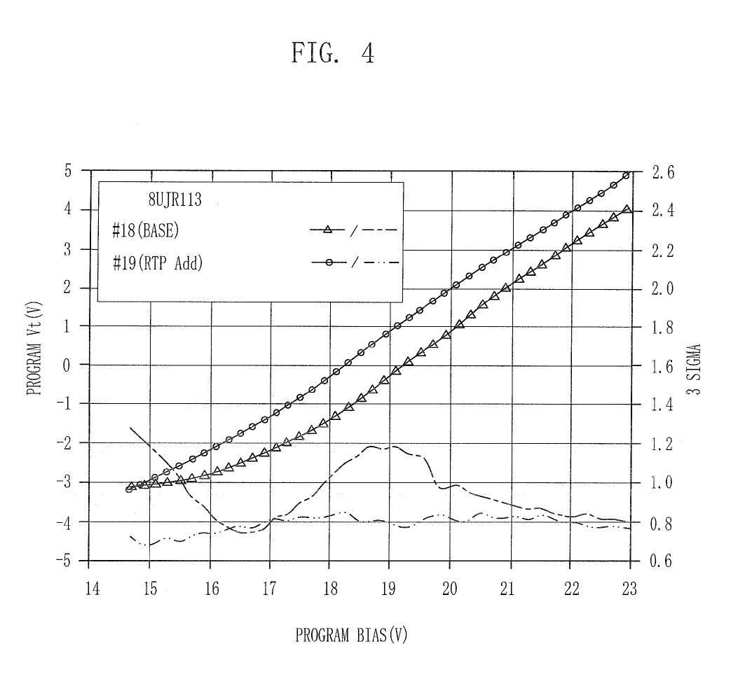

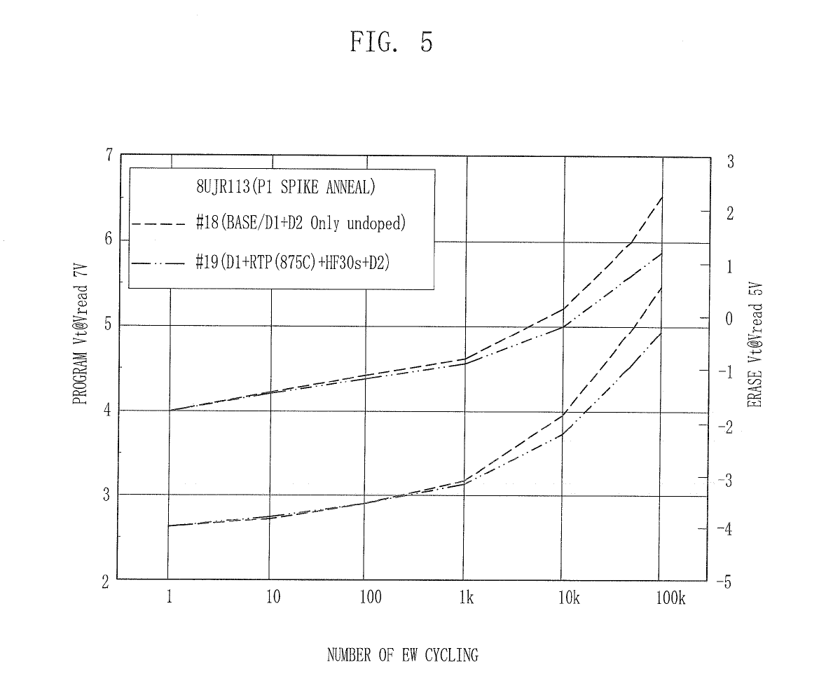

FIGS. 4 and 5 illustrate graphs for comparing a characteristic of the device fabricated by the prior art with that of a device fabricated by an embodiment of the present invention.

FIG. 4 illustrates a graph of cell threshold voltages after a programming operation is performed in a incremental step pulse programming scheme (ISPP) method according to the prior art and the embodiment of the present invention. Here, an X axis shows a bias voltage applied when programming operation is performed and a Y axis shows cell threshold voltages after the programming operation is performed.

FIG. 5 illustrates a graph of a ratio for a cell threshold voltage to a number of erase/write (E/W) cycling according to the prior art and the embodiment of the present invention. Here, an X axis shows the number of the E/W cycling and a Y axis shows a cell threshold voltage derived after the programming operation is performed and a cell threshold voltage derived after the erasing operation is performed.

Referring to FIGS. 4 and 5, the threshold voltage characteristic of the device fabricated by the present invention (#19, the device fabricated by the method in which the thermal treatment on the first polysilicon layer is used) is highly improved as compared with the device fabricated by the prior art (#18, the device fabricated by the method in which the thermal treatment on the first polysilicon layer is not performed).

While the present invention has been described with respect to the specific embodiments, the above embodiment of the present invention is illustrative and not limitative. It will be apparent to those skilled in the art that various changes and modifications may be made without departing from the spirit and scope of the invention as defined in the following claims.

What is claimed is:

1. A semiconductor device comprising:
a conductive layer including first and second polysilicon layers having different grain sizes, wherein the first polysilicon layer is crystallized to increase its grain size.

2. A method of forming a conductive layer in a semiconductor device, the method comprising:
forming a first polysilicon layer over a substrate, the first polysilicon being undoped;
crystallizing the undoped first polysilicon layer to grow a grain size of the first polysilicon layer; and
forming a second polysilicon layer over the first polysilicon layer, the second polysilicon layer being doped.

3. The method of claim 2, wherein crystallizing the first polysilicon layer is performed through a thermal treatment.

4. The method of claim 3, wherein the thermal treatment is carried out by any one of a rapid thermal process (RTP), a furnace annealing process or a laser annealing process, or a combination thereof.

5. The method of claim 4, wherein the RTP is performed in a range from approximately 600° C. to approximately 1,000° C.

6. The method of claim 4, wherein the furnace annealing process is performed in a range from approximately 600° C. to approximately 900° C.

7. The method of claim 2, wherein crystallizing the first polysilicon layer includes:
forming a chemical vapor deposition (CVD) layer over the first polysilicon layer; and
thereafter, removing the CVD layer, wherein the first polysilicon layer is crystallized by heat associated with forming the CVD layer.

8. The method of claim 7, wherein the CVD layer includes tetraethyleorthosilicate (TEOS) or high temperature oxide (HTO).

9. The method of claim 2, wherein crystallizing the first polysilicon layer includes:
forming a thermal oxide layer over the first polysilicon layer; and
thereafter, removing the thermal oxide layer,
wherein the first polysilicon layer is crystallized by heat associated with forming the thermal oxide layer,
wherein the thermal oxide layer is formed by an oxidation process using dry or wet radical ions.

10. The method of claim 3, wherein the first polysilicon layer is formed to have a thickness ranging from approximately 30 percent to approximately 50 percent of an entire thickness of the conductive layer.

11. The method of claim 3, wherein the second polysilicon layer is formed to have a thickness ranging from approximately 50 percent to approximately 70 percent of an entire thickness of the conductive layer.

12. The method of claim 3, wherein the second polysilicon layer is formed using a doped polysilicon layer having a doping concentration greater than that of the first polysilicon layer.

13. The method of claim 3, wherein the first polysilicon layer includes a polysilicon layer that is not doped with impurities.

14. The method of claim 3, further comprising forming a gate insulation layer over the substrate before the first polysilicon layer is formed.

15. The method of claim 3, wherein forming the second polysilicon layer and forming the first polysilicon layer are performed by an ex-situ process.

16. A nonvolatile memory device comprising:
a substrate;
a floating gate formed over the substrate and including first and second polysilicon layers, the first polysilicon layer having a grain size that is bigger than that of the second polysilicon layer,
wherein the first polysilicon layer is exposed to heat after the first polysilicon layer is formed over the substrate.

17. A method of forming a floating gate in a nonvolatile memory device, the method comprising:
forming an undoped polysilicon layer over a substrate;
crystallizing the undoped polysilicon layer to increase a grain size of the undoped polysilicon layer; and
forming a doped polysilicon layer over the undoped polysilicon layer after the crystallizing step, so that dopants from the doped polysilicon is diffused into the undoped polysilicon layer.

18. The method of claim 17, wherein crystallizing step includes a thermal treatment.

19. The method of claim 18, wherein the thermal treatment is carried out by any one of a rapid thermal process (RTP), a furnace annealing process or a laser annealing process, or a combination thereof.

20. The method of claim 17, wherein crystallizing the first polysilicon layer includes:
forming a thermal oxide layer over the undoped polysilicon layer; and
removing the thermal oxide layer,
wherein heat associated with the forming the thermal oxide layer is used to crystallize the undoped polysilicon layer.

21. The method of claim 20, wherein the thermal oxide layer is formed by an oxidation process using dry or wet radical ions.

22. The method of claim 18, wherein crystallizing the undoped polysilicon layer includes:
forming a chemical vapor deposition (CVD) layer over the undoped polysilicon layer; and
thereafter, removing the CVD layer, wherein the undoped polysilicon layer is crystallized by heat associated with forming the CVD layer.

23. The method of claim 18, further comprising forming a tunneling insulation layer over the substrate before the undoped polysilicon layer is formed.
